(19) United States
(12) Patent Application Publication
(10) Pub. No.: US 2013/0300968 A1
(43) Pub. Date: Nov. 14, 2013

(54) SUBSTRATE FOR LIQUID CRYSTAL DISPLAY PANEL AND LIQUID CRYSTAL DISPLAY DEVICE

(71) Applicants: Nami Okajima, Osaka (JP); Masahiro Fujiwara, Osaka (JP)

(72) Inventors: Nami Okajima, Osaka (JP); Masahiro Fujiwara, Osaka (JP)

(73) Assignee: SHARP KABUSHIKI KAISHA, Osaka (JP)

(21) Appl. No.: 13/980,663

(22) PCT Filed: Jan. 19, 2012
(86) PCT No.: PCT/JP2012/051028

§ 371 Date: Jul. 19, 2013

(30) Foreign Application Priority Data
Jan. 27, 2011 (JP) 2011-015291

(51) Int. Cl. G02F 1/1362; H01L 29/786

(52) U.S. Cl. CPC G02F 1/136209; H01L 29/78609
USPC 349/43; 257/57; 257/66

(57) ABSTRACT

The present invention provides a substrate for a liquid crystal display panel, the substrate being capable of effectively suppressing the occurrence of crosstalk and flicker without decreasing the aperture ratio. One aspect of the present invention is a substrate for a liquid crystal display panel, provided with: a light-shielding electroconductive member; a thin-film transistor arranged in a layer above the light-shielding electroconductive member; a transparent electrode wiring line arranged in a layer above the thin-film transistor, and a pixel electrode arranged in a layer above the transparent electrode wiring line. The light-shielding electroconductive member is a light-shielding element that covers the channel region of the thin-film transistor and is a wiring line connected to the transparent electrode wiring line, and the transparent electrode wiring line has a portion opposing the pixel electrode, with an insulating film disposed therebetween.

### TECHNICAL FIELD

The present invention relates to a substrate for a liquid crystal display panel and a liquid crystal display device. More specifically, the present invention relates to a substrate for a liquid crystal display panel suitable for an active matrix method that uses thin-film transistors, and to a liquid crystal display device provided with the substrate for a liquid crystal display panel.

### BACKGROUND ART

Liquid crystal display devices are display devices that use a liquid crystal composition for display. A representative display method therefor is a method that controls the light transmission amount by applying a voltage to liquid crystal sealed between a pair of substrates to change the orientation state of liquid crystal in accordance with the applied voltage.

The passive matrix method and active matrix method are well known as driving methods for liquid crystal display devices. In typical active matrix liquid crystal display devices, gate bus lines and source bus lines that intersect each other perpendicularly are provided in a grid pattern. Thin-film transistors are arranged on respective regions demarcated in a matrix by the gate bus lines and the source bus lines. When a scan signal is inputted to the gate electrode of a thin-film transistor through the gate bus line, the thin-film transistor, which is a switching element, changes to an ON state. When the thin-film transistor is in an ON state, the image signal flowing through the source bus line is transmitted from the source electrode to the drain electrode of the thin-film transistor, and then further transmitted to the pixel electrode. The image signal inputted to each pixel electrode corresponds to the voltage applied between the pixel electrode, which is provided for each pixel, and the common electrode, which is shared by all of the pixels. In other words, the image signal corresponds to the voltage applied to the liquid crystal of each pixel. The orientation state of the liquid crystal is changed corresponding to the voltage applied to the liquid crystal, thereby controlling the amount of light that can pass through the liquid crystal for each pixel. This enables the display of high-resolution images. Such an active matrix method is commonly used in TVs, monitors, and the like that use a large number of pixels to perform a display.

In the active matrix method, in order to maintain the image signal inputted to the pixel electrode, namely to maintain the liquid crystal capacitance while the thin-film transistor is in an OFF state, an auxiliary capacitance is normally formed in each pixel. This auxiliary capacitance is formed by providing an auxiliary capacitance wiring line opposing the pixel electrode of each pixel, with an insulating film therebetween, for example. A configuration in which a light-shielding pattern, formed as a black mask, is electrically connected to the auxiliary capacitance wiring line is known as a technology to lower the resistance of this auxiliary capacitance wiring line (see Patent Document 1).

Some thin-film transistors used in the active matrix method have a leakage of current when light is radiated onto the channel. The leakage of current during the OFF state (the OFF-leak current) causes malfunction of the thin-film transistor, and thus a technology is known which attempts to suppress OFF-leak current by arranging a light-shielding layer in the layer above or the layer below the thin-film transistor (see Patent Documents 2 and 3).

The fringe field switching (FFS) mode is known as a display mode for liquid crystal display devices. The FFS mode has a structural characteristic in which the pixel electrode and the common electrode are arranged on the same substrate above and below an insulating film (see Patent Document 4).

### RELATED ART DOCUMENTS

### Patent Documents

Patent Document 1: Japanese Patent Application Laid-Open Publication No. H8-234239

Patent Document 2: Japanese Patent Application Laid-Open Publication No. 2001-42361

Patent Document 3: Japanese Patent Application Laid-Open Publication No. 2000-131713

Patent Document 4: Japanese Patent Application Laid-Open Publication No. 2008-165134

### SUMMARY OF THE INVENTION

### Problems to be Solved by the Invention

It is necessary to effectively suppress the occurrence of crosstalk and flicker in the active matrix method. Crosstalk is the phenomenon where drive signals leak into pixels that are not to be driven. Flicker is the phenomenon where a screen flickers with a cycle longer than the residual image time of the eye (15-20 msec, 60-50 Hz frequency), and occurs when noise signals mix into the display signals and screen brightness changes in that cycle.

Lowering the resistance of the auxiliary capacitance wiring line is an effective countermeasure to crosstalk, and a method is possible where a new wiring line is connected in parallel to the auxiliary capacitance wiring line, for example. As a countermeasure to flicker, a method is known where a light-shielding layer is provided for reducing the OFF-leak current of the thin-film transistor.

However, there was room for improvement in that the aperture ratio as well as the degree of freedom for wiring line layout decrease when a new wiring line is provided as a countermeasure to crosstalk. A method was needed that effectively solves both crosstalk and flicker.

The present invention was made in view of the abovementioned situation, and aims at providing a substrate for a liquid crystal display panel that can effectively suppress the occurrence of crosstalk and flicker without reducing the aperture ratio, and a liquid crystal display device provided with the substrate for the liquid crystal display panel.

### Means for Solving the Problems

The inventors of the present invention, upon various research into methods for effectively suppressing the occurrence of crosstalk and flicker in a substrate for a liquid crystal display panel driven by the active matrix method, have focused on combining a method to solve crosstalk and a method to solve flicker, from the viewpoint of avoiding a decrease in the aperture ratio. The inventors of the present invention have conceived of being able to admirably solve the abovementioned problems, and thus leading to the present invention, by arranging in a layer below a thin-film transistor a light-shielding electroconductive member that covers the channel region of the thin-film transistor, and by using this light-shielding electroconductive member as a wiring line that is connected in parallel to the transparent electrode wiring line.

In other words, one aspect of the present invention is a substrate for a liquid crystal display panel, provided with: a light-shielding electroconductive member; a thin-film transistor arranged in a layer above the light-shielding electroconductive member; a transparent electrode wiring line arranged in a layer above the thin-film transistor; and a pixel electrode arranged in a layer above the transparent electrode wiring line, wherein the light-shielding electroconductive member is a light-shielding element that covers a channel region of the thin-film transistor, and is a wiring line connected in parallel to the transparent electrode wiring line, and wherein the transparent electrode wiring line has a portion opposing the pixel electrode, with an insulating film disposed therebetween.

In the present invention, the light-shielding electroconductive member is provided in a layer below the thin-film transistor as a light-shielding element that covers the channel region of the thin-film transistor. The light-shielding electroconductive member can prevent light emitted from the backlight unit being radiated onto the channel region of the thin-film transistor. As a result, OFF-leak current of the thin-film transistor is reduced, and the occurrence of flicker is prevented.

The light-shielding electroconductive member is also a wiring line connected in parallel to the transparent electrode wiring line. The transparent electrode wiring line has a portion opposing the pixel electrode, with an insulating film disposed therebetween, and forms an auxiliary capacitance. Therefore, the light-shielding electroconductive member functions as a wiring line connected in parallel to the transparent electrode wiring line to enable the lowering in resistance of the entire wiring line that forms the auxiliary capacitance. As a result, the occurrence of crosstalk is prevented.

In one example of the present invention, an electrical conductivity of the light-shielding electroconductive member is higher than an electrical conductivity of the transparent electrode wiring line. According to this example, a reduction in the resistance of the wiring line that forms the auxiliary capacitance is sufficiently obtained and the occurrence of crosstalk can be effectively suppressed.

In one example of the present invention, the light-shielding electroconductive member includes a metal layer or an alloy layer containing at least one type of element selected from a group including tantalum, titanium, tungsten, molybdenum, and aluminum. According to this example, light-shielding of the channel region of the thin-film transistor can be combined with a reduction in resistance of the wiring line forming the auxiliary capacitance, and the occurrence of flicker and crosstalk can be effectively suppressed.

In one example of the present invention, the transparent electrode wiring line contains indium tin oxide or indium zinc oxide. Indium tin oxide and indium zinc oxide are materials with a relatively high electrical conductivity, and thus can significantly lower the resistance of the whole wiring line that forms the auxiliary capacitance by the light-shielding electroconductive member being connected in parallel to the transparent electrode wiring line as in the present invention, and the occurrence of crosstalk can be markedly suppressed.

In one example of the present invention, an insulating film with a film thickness of 300 nm or above is provided between the light-shielding electroconductive member and a gate electrode of the thin-film transistor. According to this example, the effect that the potential change of the light-shielding electroconductive member exerts on the operation of the thin-film transistor can be sufficiently suppressed.

In another aspect of the present invention, a liquid crystal display device provided with the abovementioned substrate for a liquid crystal display panel has a voltage applied to liquid crystal by the pixel electrode and the transparent electrode wiring line. In this liquid crystal display device, the transparent electrode wiring line functions not just as the auxiliary capacitance wiring line, but also as the common electrode. A fringe field switching (FFS) mode liquid crystal display device is one example of such a liquid crystal display device.

In yet another aspect of the present invention, a liquid crystal display device includes the substrate for a liquid crystal display panel, and a backlight. This liquid crystal display device is a so-called transmissive liquid crystal display device, or a transflective liquid crystal display device.

### Effects of the Invention

According to a substrate for a liquid crystal display panel and a liquid crystal display device of the present invention, a light-shielding element provided for reducing OFF-leak current of the thin-film transistor is used to lower the resistance of an auxiliary capacitance wiring line, thereby making it possible to effectively suppress the occurrence of crosstalk and flicker without lowering the aperture ratio.

### BRIEF DESCRIPTION OF THE DRAWINGS

FIG. 1 is a cross-sectional schematic view showing a configuration of a substrate for a liquid crystal display panel of Comparison Example 1.

FIG. 2 is a cross-sectional schematic view showing a configuration of a substrate for a liquid crystal display panel of Comparison Example 2.

FIG. 3 is a plan schematic view showing a configuration of a substrate for a liquid crystal display panel of Embodiment 1.

FIG. 4 is a cross-sectional schematic view showing a cross-section of the substrate for a liquid crystal display panel of FIG. 3.

FIG. 5 is a diagram showing the principle of crosstalk occurrence.

FIG. 6 is a plan schematic view showing a configuration of a substrate for a liquid crystal display panel of Embodiment 2.

FIG. 7 is a cross-sectional schematic view showing a cross-section of the substrate for a liquid crystal display panel of FIG. 6.

### DETAILED DESCRIPTION OF EMBODIMENTS

### Embodiment 1

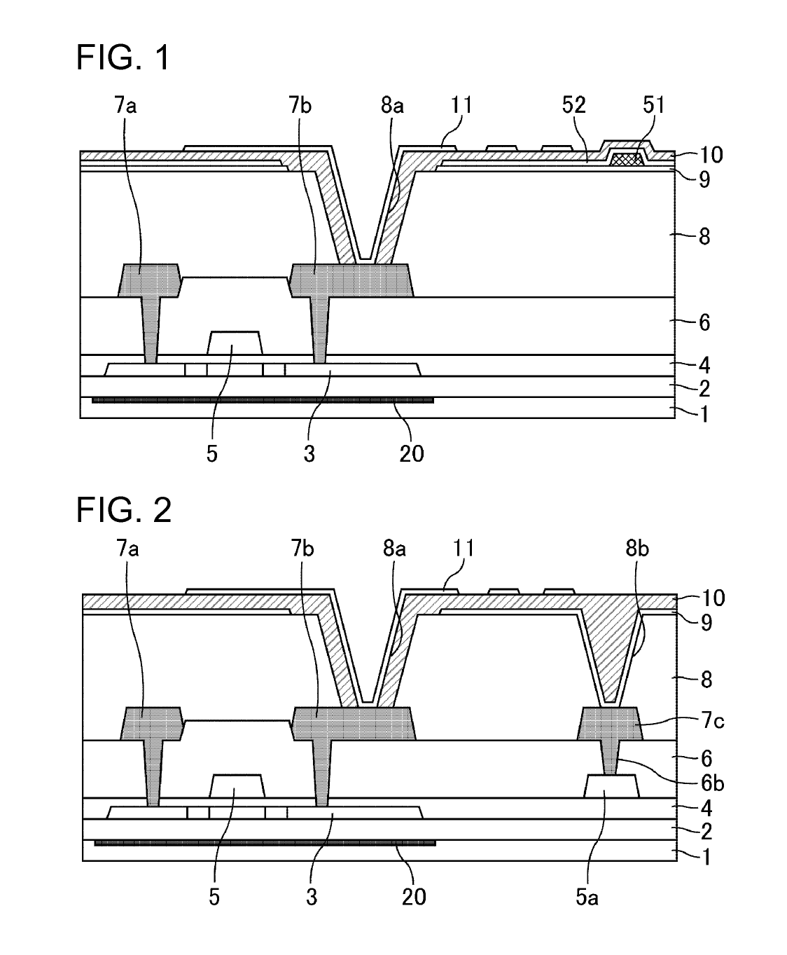

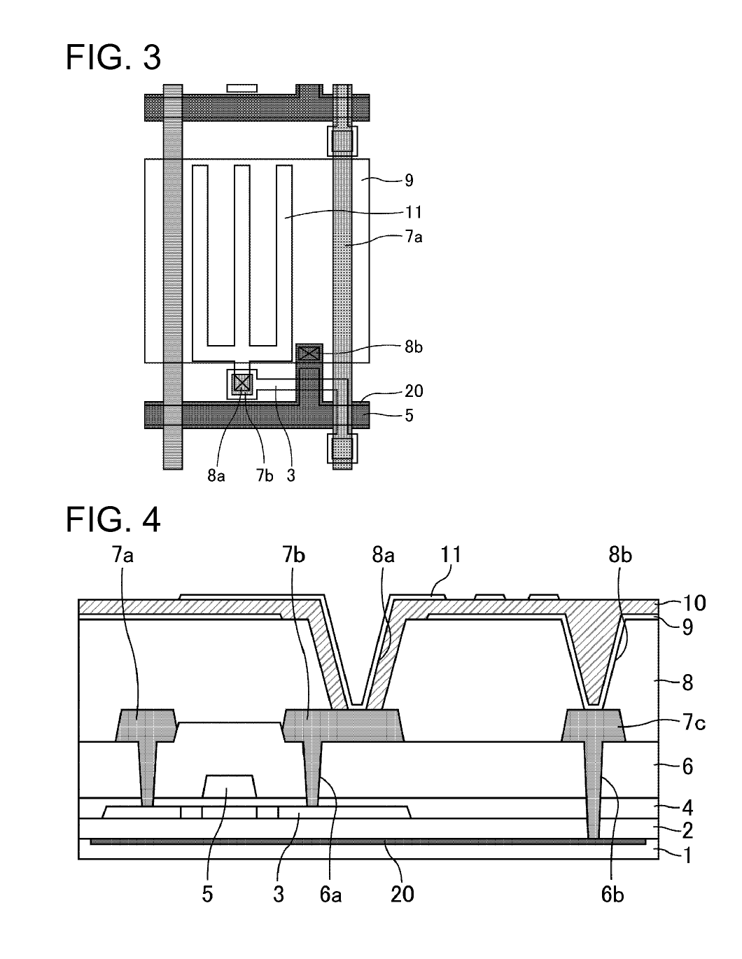

FIG. 1 is a cross-sectional schematic view showing a configuration of a substrate for a liquid crystal display panel of Comparison Example 1. FIG. 2 is a cross-sectional schematic view showing a configuration of a substrate for a liquid crystal display panel of Comparison Example 2. FIG. 3 is a plan schematic view showing a configuration of a substrate for a liquid crystal display panel of Embodiment 1. FIG. 4 is a cross-sectional schematic view showing a cross-section of the substrate for a liquid crystal display panel of FIG. 3. The substrate for a liquid crystal display panel of Comparison Examples 1 and 2 were not disclosed in the related art documents, but rather were created by the inventors of the present invention for contrast with the substrate for a liquid crystal display panel of the present embodiment.

The substrate for a liquid crystal display panel is built into a liquid crystal display device, with the liquid crystal display panel being manufactured by bonding together a pair of substrates for a liquid crystal display panel and sealing a liquid crystal layer therebetween, for example. The substrate for a liquid crystal display panel of the present embodiment is provided with thin-film transistors necessary for driving by the active-matrix method, and is also called a thin-film transistor array substrate or an active matrix substrate.

As shown in FIGS. 1 to 4, the substrates for a liquid crystal display panel of Comparison Examples 1 and 2 and the present embodiment have a pixel electrode 11 and a common electrode 9 provided on the same substrate. The orientation of the liquid crystal molecules can be controlled in a plane parallel to the substrate surface in correspondence with a voltage applied between the pixel electrode 11 and the common electrode 9. An interelectrode insulation film 10 is provided between the pixel electrode 11 and the common electrode 9. In other words, the substrate for a liquid crystal display panel of Comparison Examples 1 and 2 and the present embodiment is used in a fringe field switching mode liquid crystal display device, which is one type of transverse electric field mode.

The common electrode 9 also has a role of forming an auxiliary capacitance in a portion opposing the pixel electrode 11 via the interelectrode insulating film 10.

Because an electric field occurs in the display region in a direction parallel to the substrate surface, transparent electrodes, which light emitted from the backlight can pass through, are used for the pixel electrode 11 and the common electrode 9. However, since the common electrode 9 is formed of a transparent conductive material such as indium tin oxide (ITO) or indium zinc oxide (IZO), it is difficult to sufficiently decrease the wiring line resistance, and thus leading to the occurrence of crosstalk.

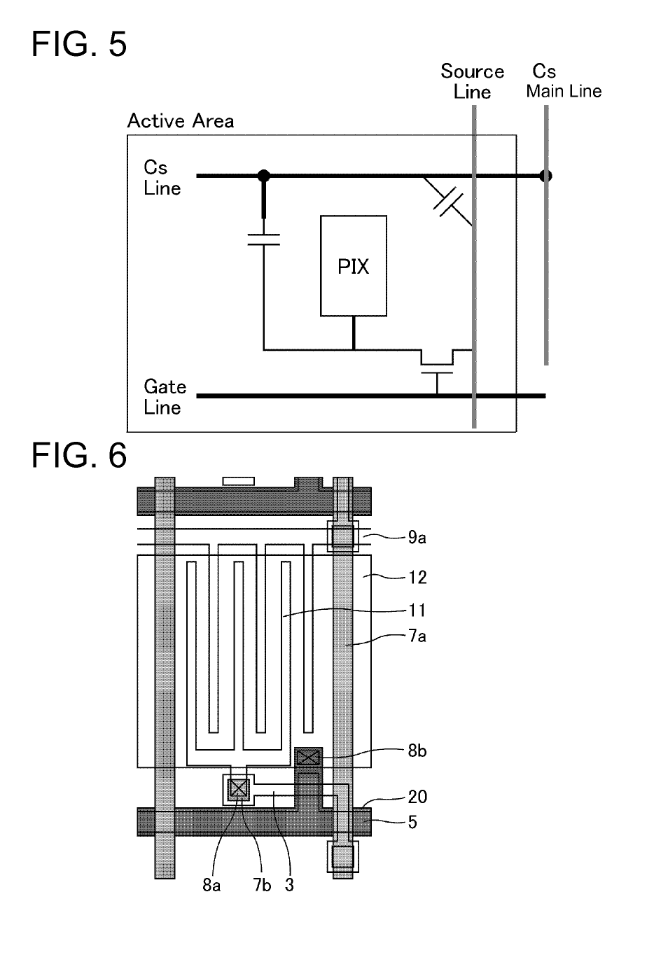

FIG. 5 is a diagram showing the principle of crosstalk occurrence. In FIG. 5, crosstalk is explained which occurs when a wiring line part (Cs Line), which is branched from the main line (Cs Main Line) of the auxiliary capacitance wiring line, intersects with a source line (Source Line) in an active area (Active Area) where a plurality of pixel electrodes (PIX) are arrayed. First, due to the change in potential of the source line (Source Line) when signals are being written to the thin-film transistors, the capacitance of the intersection part of the source line and the wiring line part (Cs Line) changes, the effect of which causes the potential of the auxiliary capacitance wiring line to change. At this time, if the wiring resistance of the auxiliary capacitance wiring line is high, then the potential of the auxiliary capacitance wiring line cannot return to the desired potential by the time the thin-film transistor changes to OFF. When the potential of the auxiliary capacitance wiring line returns to the desired potential after the thin-film transistor changes to OFF, the potential of the pixel electrode (PIX) will change. The size of potential change of the source line is different depending on whether the pixels are in an ON state or an OFF state, and thus the size of potential change of the pixel electrodes will also be different. As a result, difference in brightness will occur when performing halftone display with the same gradation, and crosstalk will be visible. Such crosstalk has a tendency to be markedly easy to occur on substrates such as those with a high-resolution arrangement of pixels, and those using a transparent electrode wiring line, with a relatively high wiring resistance, as an auxiliary capacitance wiring line. This tendency is similar with the occurrence of flicker.

In Comparison Example 1, as shown in FIG. 1, the wiring resistance is reduced by providing, on the common electrode 9, wiring line layers 51 and 52 made of a metal that has a lower resistance than the transparent conductive material.

In Comparison Example 2, as shown in FIG. 2, contact holes 6b and 8b are used to connect the common electrode 9 to an auxiliary capacitance wiring line 5a, which is provided in the same layer as a gate electrode 5.

In comparison, in the present embodiment as shown in FIGS. 3 and 4, the contact holes 6b and 8b are used to connect the common electrode (the transparent electrode wiring line) 9 to the light-shielding film (the light-shielding electroconductive member) 20, which is provided in a lower layer. The lowering in resistance of the whole wiring line forming the auxiliary capacitance is possible due to the light-shielding film 20 functioning as a wiring line connected in parallel to the common electrode 9. As a result, the occurrence of crosstalk can be prevented. The light-shielding film 20 has light-shielding properties and conductive properties, and it is preferable for an electrical conductivity of the light-shielding film 20 to be higher than an electrical conductivity of the common electrode 9. A preferable form of the light-shielding film 20 includes a metal layer or an alloy layer containing at least one type of element selected from a group including tantalum, titanium, tungsten, molybdenum, and aluminum, for example. It is preferable for the light-shielding film 20 to be made of molybdenum (Mo), in particular.

The light-shielding film 20 shields the channel region of the thin-film transistor from light being radiated onto the channel region from the backlight unit, thereby reducing the OFF-leak current of the thin-film transistor. The light-shielding film 20 is a member also provided in Comparison Example 1. Therefore, the method of connecting the light-shielding film 20 to the common electrode 9 can be accomplished more easily than adding the new wiring line layers 51 and 52 as in Comparison Example 1. In other words, the method of connecting the light-shielding film 20 to the common electrode 9 can be accomplished by changing the arrangement pattern of the light-shielding film 20, forming the contact hole 6b at the same time as the contact hole 6a, and forming the contact hole 8b at the same time as the contact hole 8a.

As in Comparison Example 2, when arranging the auxiliary capacitance wiring line 5a in the same layer as the gate electrode 5 of the thin-film transistor and the gate line to which the gate electrode 5 is connected, it is necessary for the gate electrode 5 or the gate line and the auxiliary capacitance wiring line 5a to not short-circuit, and thus there are design rule constraints. However, when using the light-shielding film 20 of the present embodiment, it is not necessary to adjust the design in consideration of short-circuiting with other members, so there are design rule advantages.

Next, by explaining one example of a method to manufacture the substrate for a liquid crystal display panel of the present embodiment, the details of the configuration thereof will be made clear.

First, a metal film for forming the light-shielding film 20 is deposited on one surface of a glass substrate 1, which acts as the base substrate. A material or the like that has an element such as Ta, Ti, W, Mo, or Al as a main component is used for the metal film. It is preferable to use a metal film that has Mo as a main component, for example. A resist pattern is formed, by photolithography, on portions that overlap the formation region of the light-shielding film 20. Next, the light-shielding film 20 is obtained by etching the metal film with the resist pattern as the mask. An insulating film such as a silicon (Si) film may also be used for the formation of the light-shielding film 20 instead of a metal film. In such a case, it is necessary to dope the insulating film to raise the conductivity thereof. The thickness of the light-shielding film 20 is set at 50 nm or above, for example. CVD (chemical vapor deposition) or sputtering is used as the deposition method for the light-shielding film 20, for example.

Next, a buffer film 2 (also called a base coat film) is deposited to cover the light-shielding film 20. The buffer film 2 may be one layer or may be many layers, and a silicon oxide film (SiO₂), a silicon nitride film (SiNₓ), a silicon nitride oxide film (SiNO) or the like is used. A multilayer film of a silicon oxide film and a silicon nitride oxide film (SiO₂/SiNO), or a silicon oxide film (SiO₂) is preferably used, for example. The thickness of the buffer film 2 is set at 100 nm-500 nm, for example. It is preferable for the thickness of the buffer film 2 to be 300 nm or above, in consideration of suppressing the effect the light-shielding film 20 exerts on the operation of the thin-film transistor. CVD is used as the deposition method for the buffer film 2, for example.

A semiconductor layer 3 that is used by the pixel TFTs and the driver TFTs is formed on the buffer film 2. The semiconductor layer 3 is formed by patterning a silicon film such as a continuous grain silicon (CGS) film, a low temperature polysilicon (LPS) film, or an amorphous silicon (α-Si) film. CVD is used as the deposition method for the silicon film, for example.

As an example, a method to deposit a continuous grain silicon film and form the semiconductor layer 3 by patterning this is shown below. First, a silicon oxide film and an amorphous silicon film are deposited in that order on the buffer film 2. Next, a nickel thin film that acts as a catalyst for accelerating crystallization is formed on the surface layer of the amorphous silicon film. Next, the nickel thin film and the amorphous silicon film are made to react by laser annealing, and a crystalline silicon layer is formed on the boundary of these. Afterwards, the unreacted portion of the nickel thin film and portions where nickel silicide has formed are removed by etching or the like. Next, when crystallization has progressed by performing laser annealing on the remaining silicon film, a silicon film made of continuous grain silicon is obtained.

Next, a resist pattern is formed on the source, drain, and channel of the pixel TFT part and the driver TFT part of the silicon film, and etching is performed with this as the mask. By doing this, the semiconductor layer 3 for each TFT is obtained.

Next, a gate insulating film 4 is deposited to cover the semiconductor layer 3. The gate insulating film 4 may be one layer or may be many layers, and a silicon oxide film (SiO₂), a silicon nitride film (SiNₓ), a silicon nitride oxide film (SiNO) or the like is used. A silicon oxide film (SiO₂), a silicon nitride film (SiNₓ), or a multilayer film of a silicon nitride film and a silicon oxide film (SiNₓ/SiO₂) is preferably used, for example. The thickness of the gate insulating film 4 is set at 10 nm-120 nm, for example. CVD is used as the deposition method for the gate insulating film 4, for example. Specifically, if forming a silicon oxide film, one method is to use SiH₄ and N₂O, or SiH₄ and O₂ as the starting gas to perform PECVD.

Next, in order to adjust the dose of the semiconductor layer 3, channel doping is performed on the semiconductor layer 3. Specifically, using a p-type impurity such as boron (B) or indium (In), ion implantation is performed with the implantation energy set at 10 KeV to 80 KeV, and with the dose set at 5×10¹⁴ (ion) to 2×10¹⁶ (ion), for example. At this time, the impurity concentration after implantation is preferably 1.5×10²⁰ to 3×10²¹ (ions/cm³).

Next, the gate electrode 5 is formed. Specifically, first a metal material that has an element such as Ta, Ti, W, Mo, or Al as a primary component is used to form a conductive layer by sputtering, vacuum deposition, or the like. For the conductive layer, a multilayer film of tungsten and tantalum nitride (W/Tan), a molybdenum film (Mo), a molybdenum-tungsten alloy film (MoW), or a multilayer film of a titanium film and an aluminum film (Ti/Al) is preferably used, for example. Next, a resist pattern is formed, by photolithography, on portions that overlap the formation region of the gate electrode on the conductive layer. When etching is performed with this as the mask, the gate electrode 5 is formed.

Next, ion implantation for forming a p-type diffusion layer is performed. By doing this, a p-type diffusion layer of a p-type driver TFT is formed. Specifically, first a resist pattern provided with an opening is formed on portions overlapping the formation region of the p-type diffusion layer. Next, using a p-type impurity such as boron (B) or indium (In), ion implantation is performed with the implantation energy set at 10 KeV to 80 KeV, and with the dose set at 5×10¹⁴ (ion) to 2×10¹⁶ (ion), for example. At this time, the impurity concentration after implantation is preferably 1.5×10²⁰ to 3×10²¹ (ions/cm³). After ion implantation has ended, the resist pattern is removed.

Next, ion implantation for forming an n-type diffusion layer is performed. In the present embodiment, an n-type diffusion layer is formed in the driver TFTs and the pixel TFTs. Specifically, first a resist pattern provided with an opening is formed on portions that overlap source regions and drain regions of an n-type driver TFT and a pixel TFT. Next, using an n-type impurity such as phosphorous (P) or arsenic (As), ion implantation is performed with the implantation energy set at 10 KeV to 100 KeV, and with the dose set at 5×10¹⁴ (ion) to 2×10¹⁶ (ion), for example. Also at this time, the impurity concentration after implantation is preferably 1.5×10²⁰ to 3×10²¹ (ions/cm³). After ion implantation has ended, the resist pattern is removed.

With the above steps, a pixel TFT, a p-type driver TFT, and an n-type driver TFT are manufactured. In the case of a liquid crystal panel that is only driven by n-type TFTs, the ion implantation step for forming a p-type diffusion layer is not necessary.

In pixel TFTs where a low leakage current is demanded, an LDD structure may be formed by providing a region that has been implanted with phosphorous at a low concentration on the outside of the channel.

Next, an interlayer insulating film 6 is formed. The interlayer insulating film 6 may be one layer or may be many layers, and a silicon oxide film (SiO₂), a silicon nitride film (SiNₓ), a silicon nitride oxide film (SiNO) or the like is used. A multilayer film of a silicon oxide film and a silicon nitride film (SiO₂/SiNₓ), a multilayer film of a silicon oxide film, a silicon nitride film, and a silicon oxide film (SiO₂/SiNₓ/SiO₂), a silicon oxide film (SiO₂), or a silicon nitride film (SiNₓ) is preferably used, for example. CVD is used as the deposition method for the interlayer insulating film 6, for example. Specifically, if forming a silicon oxide film, one method is to use SiH₄ and N₂O, or SiH₄ and O₂ as the starting gas to perform PECVD.

A through-hole that reaches the semiconductor layer 3 by going through the gate insulating film 4 and the interlayer insulating film 6, and a through-hole that reaches the light-shielding layer 20 by going through the buffer film 2, the gate insulating film 4, and the interlayer insulating film 6 are also formed. Specifically, the through-holes are formed by using photolithography to form a resist pattern and performing etching with this as the mask. By filling into the through-holes a conductive material used for a source electrode 7a and a drain electrode 7b, as described later, the contact hole 6a for electrically connecting the semiconductor layer 3 and the source electrode 7a or the drain electrode 7b and the contact hole 6b for electrically connecting the light-shielding film 20 and a relay electrode 7c are formed.

Next, the source electrode 7a, the drain electrode 7b, and the relay electrode 7c are formed. Specifically, first a metal material that has an element such as Ta, Ti, W, Mo, or Al as a primary component is used to form a conductive layer by sputtering, vacuum deposition, or the like. For the conductive layer, a multilayer film of a titanium film, an aluminum film, and a titanium film (Ti/Al/Ti), a multilayer film of a titanium film and an aluminum film (Ti/Al), a multilayer film of a titanium nitride film, an aluminum film, and a titanium nitride film (TiN/Al/TiN), a multilayer film of a molybdenum film, an aluminum-neodymium film, and a molybdenum film (Mo/Al—Nd/Mo), or a multilayer film of a molybdenum film, an aluminum film, and a molybdenum film (Mo/Al/Mo) is preferably used, for example. Next, a resist pattern is formed, by photolithography, on portions that overlap formation regions of the source electrode 7a, the drain electrode 7b, and the relay electrode 7c on the conductive layer. When etching is performed with this as the mask, the source electrode 7a, the drain electrode 7b, and the relay electrode 7c are formed.

Next, a transparent resin film (a planarizing film) 8 is formed in order to planarize a surface for forming the common electrode 9, as described later. The transparent resin film 8 has an opening provided on an area where the drain electrode 7b is formed in order to electrically connect the drain electrode 7b and the pixel electrode 11, which is formed later. Furthermore, the transparent resin film 8 has an opening provided on an area where the relay electrode 7c is formed in order to electrically connect the relay electrode 7c and the common electrode 9, which is formed later. The opening can be created by photolithography and etching if a photosensitive resin is used as the material for the transparent resin film 8.

Next, the common electrode (the lower layer transparent electrode) 9 is deposited on the transparent resin film 8. At this time, the common electrode 9 is also arranged inside the opening, which is provided so as to go through the transparent resin film 8 in the region where the relay electrode 7c is formed, and thus forming the contact hole 8b. Specifically, after a single conductive film is formed on the transparent resin film 8 and inside the opening, the conductive film is patterned by photolithography and etching. The common electrode 9 is an electrode for changing the orientation of liquid crystal, and also forms an auxiliary capacitance. A transparent conductive material which light emitted from the backlight can pass through is preferable as the material for the common electrode 9, and indium tin oxide (ITO) or indium zinc oxide (IZO) is preferable, for example.

Next, the interelectrode insulating film 10 is formed. The interelectrode insulating film 10 may be one layer or may be many layers, and a silicon oxide film (SiO₂), a silicon nitride film (SiNₓ), a silicon nitride oxide film (SiNO) or the like is used. CVD is used as the deposition method for the interelectrode insulating film 10, for example.

In order to electrically connect the drain electrode 7b and the pixel electrode 11, which is formed later, the interelectrode insulating film 10 has an opening in an area where the opening provided in the transparent resin film 8 is arranged. An opening can be created by photolithography and etching if a photosensitive resin is used as the material for the interelectrode insulating film 10.

Next, the pixel electrode (the upper layer transparent electrode) 11 is deposited on the interelectrode insulating film 10. At this time, the pixel electrode 11 is also arranged inside the openings formed in the transparent resin film 8 and the interelectrode insulating film 10, and thus the contact hole 8a is formed. The portion of the pixel electrode 11 on the interelectrode insulating film 10 is an electrode for changing the orientation of liquid crystal by forming a transverse electric field between the pixel electrode 11 and the common electrode 9, and is an electrode for forming an auxiliary capacitance between the pixel electrode 11 and the common electrode 9. The portion of the pixel electrode 11 inside the opening is an electrode for electrically connecting the drain electrode 7b and the pixel electrode 11. For the material of the pixel electrode 11, it is preferable to have a transparent conductive material which light emitted from the backlight can pass through, and ITO or IZO is preferable, for example. The pixel electrode 11 can be selectively arranged on necessary areas by photolithography and etching.

Afterwards, a polyimide film is printed as an alignment film (not shown). By following the above, the substrate for a liquid crystal display panel (the thin-film transistor array substrate) of the present embodiment can be manufactured.

Next, after spherical spacers are dispersed on the alignment film side of the thin-film transistor array substrate described above, the thin-film transistor array substrate and an opposite substrate are bonded together at a prescribed uniform distance. A liquid crystal layer that mainly contains liquid crystal molecules is held between the two substrates.

Next, the liquid crystal display panel is completed by attaching one polarizing plate each to the front and the back of the structure that is formed by bonding the thin-film transistor array substrate and the opposite substrate together.

To the extent necessary, a backlight unit, various types of optical films and the like are arranged on the back side of the liquid crystal display panel, and various types of optical films, a touch panel, and the like are arranged on the front side (the display surface side). An external driver circuit connects to an end of the liquid crystal panel. When such installations are complete, the liquid crystal display panel is stored inside a chassis.

By doing the above, a liquid crystal display device with the substrate for a liquid crystal display panel of the present embodiment built in is completed.

### Embodiment 2

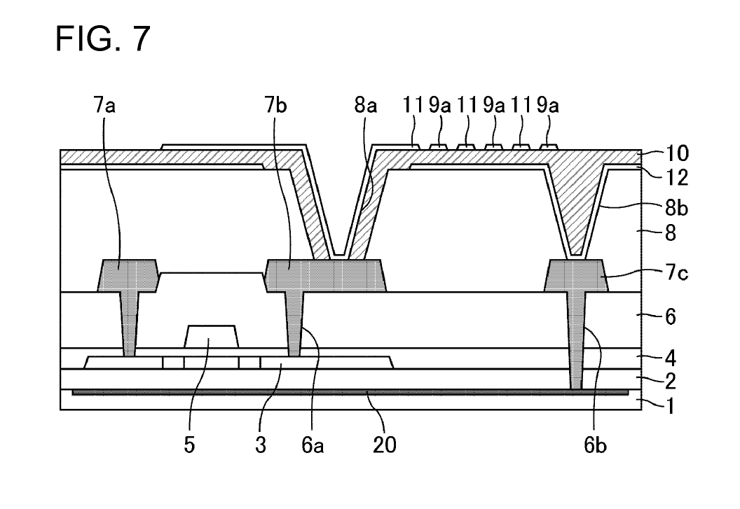

A configuration of a substrate for a liquid crystal display panel of the present embodiment will be explained below with reference to FIGS. 6 and 7. FIG. 6 is a plan schematic view showing a configuration of a substrate for a liquid crystal display panel of Embodiment 2. FIG. 7 is a cross-sectional schematic view showing a cross-section of the substrate for a liquid crystal display panel of FIG. 6.

The substrate for a liquid crystal display panel of the present embodiment is used for an in-plane switching (IPS) mode liquid crystal display device, which is a type of transverse electric field mode. The common electrode 9 of Embodiment 1 covered the entire pixel, but a common electrode 9a of the present embodiment has a comb-teeth shape in a manner similar to a pixel electrode 11, and formed in the same layer as the pixel electrode 11. In the present embodiment, an auxiliary capacitance electrode 12 (a transparent electrode wiring line) is provided below an interelectrode insulating film 10, and an auxiliary capacitance is formed by the pixel electrode 11 and the auxiliary capacitance electrode 12 opposing each other via the interelectrode insulating film 10. The rest is similar to Embodiment 1. The substrate for the liquid crystal display panel of the present embodiment can also effectively suppress the occurrence of crosstalk and flicker, in a manner similar to Embodiment 1, by the auxiliary capacitance electrode 12 and a light-shielding film 20 being electrically connected in parallel.

Various modifications can be made to each embodiment described above without departing from the technical spirit of the present invention, and configurations described in a certain embodiment may be switched with configurations described in a different embodiment, or the respective embodiments may be combined together, for example.

In each embodiment described above, the substrate for a liquid crystal display panel (the thin-film transistor array substrate) did not include a color filter, but in the present invention a color filter on array scheme that provides a color filter on the thin-film transistor array substrate may be used.

Each embodiment described above relates to a transmissive liquid crystal display device, but the substrate for a liquid crystal display panel of the present invention may be transmissive, reflective, or transflective (performing both reflective and transmissive display). In a transmissive liquid crystal display device, a backlight is provided on the back side of the liquid crystal display panel, and one polarizing plate each is provided on the surface of the display side and the back side of the liquid crystal display panel. In a reflective liquid crystal display device, a reflective film is provided on the back side behind the liquid crystal layer of the liquid crystal display panel, and a circularly polarizing plate is provided on the surface of the display side of the liquid crystal display panel. The reflective film may be a pixel electrode (a reflective electrode) provided with a reflective surface on the liquid crystal layer side, or provided separately from the pixel electrode when the pixel electrode is a transmissive electrode. There are reflective liquid crystal display devices that use external light as the display light, and those that are provided with a frontlight on the display surface side in front of the liquid crystal layer. Transflective liquid crystal display devices have a type where a transmissive region, which performs transmissive display, and a reflective region, which performs reflective display, are provided inside the pixel, and a type where a transflective film is provided inside the pixel. The transmissive region is provided with a transmissive electrode, and the reflective region is provided with a reflective electrode, or a multilayer body of a transmissive electrode and a reflective film. Transflective liquid crystal display devices have a backlight provided on the back side of the liquid crystal display panel in order to perform transmissive display, in a manner similar to the transmissive liquid crystal display panel, and one polarizing plate each is placed on the surface of the display side and the back side of the liquid crystal display panel. In order to perform reflective display, a circular polarizing plate is constituted by affixing a λ/4 retardation plate to at least the polarizing plate on the display side.

The present application claims priority to Patent Application No. 2011-015291 filed in Japan on Jan. 27, 2011 under the Paris Convention and provisions of national law in a designated State. The entire contents of which are hereby incorporated by reference.

### DESCRIPTION OF REFERENCE CHARACTERS

1 glass substrate

2 buffer film

3 semiconductor layer

4 gate insulating film

5 gate electrode

5a auxiliary capacitance wiring line

6 interlayer insulating film

6a, 6b contact hole

7a source electrode

7b drain electrode

7c relay electrode

8 transparent resin film

8a, 8b contact hole

9, 9a common electrode

10 interelectrode insulating film

11 pixel electrode

12 auxiliary capacitance electrode

20 light-shielding film

51, 52 wiring line layer

1. A substrate for a liquid crystal display panel, comprising:
a light-shielding electroconductive member;
a thin-film transistor arranged in a layer above the light-shielding electroconductive member;
a transparent electrode wiring line arranged in a layer above the thin-film transistor; and
a pixel electrode arranged in a layer above the transparent electrode wiring line,
wherein the light-shielding electroconductive member is a light-shielding element that covers a channel region of the thin-film transistor, and is a wiring line connected to the transparent electrode wiring line, and
wherein the transparent electrode wiring line has a portion opposing the pixel electrode, with an insulating film disposed therebetween.

2. The substrate for a liquid crystal display panel according to claim 1, wherein an electrical conductivity of the light-shielding electroconductive member is higher than an electrical conductivity of the transparent electrode wiring line.

3. The substrate for a liquid crystal display panel according to claim 1, wherein the light-shielding electroconductive member includes a metal layer or an alloy layer containing at least one type of element selected from a group comprising tantalum, titanium, tungsten, molybdenum, and aluminum.

4. The substrate for a liquid crystal display panel according to claim 1, wherein the transparent electrode wiring line contains indium tin oxide or indium zinc oxide.

5. The substrate for a liquid crystal display panel according to claim 1, wherein an insulating film with a film thickness of 300 nm or above is provided between the light-shielding electroconductive member and a gate electrode of the thin-film transistor.

6. A liquid crystal display device, comprising the substrate for a liquid crystal display panel according to claim 1, wherein a voltage is applied to liquid crystal by the pixel electrode and the transparent electrode wiring line.

7. A liquid crystal display device, comprising the substrate for a liquid crystal display panel according to claim 1, and a backlight.
